(19) United States
(12) Patent Application Publication
(10) Pub. No.: US 2026/0293412 A1
(43) Pub. Date: Sep. 24, 2026

(54) COMPOSITION FOR FORMING PHOTO-ACTIVE LAYER AND MANUFACTURING METHOD THEREOF

(71) Applicant: KOREA INSTITUTE OF SCIENCE AND TECHNOLOGY, Seoul (KR)

(72) Inventors: Hae Jung SON, Seoul (KR); Seongwon Yoon, Seoul (KR); Yoon Hee Jang, Seoul (KR); Kang Sik Cho, Seoul (KR); Hyunjung Jin, Seoul (KR); Taehee Kim, Seoul (KR)

(21) Appl. No.: 19/235,503

(22) Filed: Jun. 11, 2025

(30) Foreign Application Priority Data
Mar. 20, 2025 (KR) 10-2025-0035674

(51) Int. Cl. H10K 30/30; H10K 30/50; H10K 85/60

(52) U.S. Cl. CPC H10K 30/30; H10K 30/50; H10K 85/626; H10K 85/656

(57) ABSTRACT

The present specification relates to a composition for forming a photo-active layer and a preparation method thereof. A composition for forming a photo-active layer and a preparation method thereof according to an embodiment of the present invention provide an effect in which it is possible to form a uniform thin film over a wide area regardless of the surface energy of a substrate through interaction with components, and to form a uniform thin film regardless of humidity by controlling the flow of a solution during the thin film formation process.

### CROSS REFERENCE TO RELATED APPLICATION

The present application claims priority to Korean Patent Application No. 10-2025-0035674, filed on Mar. 20, 2025, the entire contents of which are hereby incorporated by this reference.

### BACKGROUND OF THE INVENTION

### Field of the Invention

The present specification discloses a composition for forming a photo-active layer and a preparation method thereof.

### Description of Government-Sponsored Research

This invention was carried out with the support of Ministry of Science and ICT under a research project of Unique Project identification number: 2710034010 and Project identification number: 2E33260 titled “Next Generation Materials for Highly Efficient Energy Storage and Conversion”, as part of the research project of “Support for research operation expenses of the Korea Institute of Science and Technology (main project expenses)” managed by National Research Foundation of Korea from Jan. 1 to Dec. 31, 2024.

This invention was carried out with the support of Ministry of Science and ICT under a research project of Unique Project identification number: 2710003240 and Project identification number: 00279418 titled “Development of Recyclable Conjugated Polymers and Upcycling Studies for Organic Electronics”, as part of the research project of “Personal Basic Research (Ministry of Science and ICT)” managed by National Research Foundation of Korea from Mar. 1, 2024 to Feb. 28, 2025.

This invention was carried out with the support of Ministry of Science and ICT under a research project of Unique Project identification number: 2710008918 and Project identification number: 00444389 titled “Development of organic and inorganic electron transporting materials for the replacement of C60 in high efficiency tandem solar cells”, as part of the research project of “Nano Material Technology Development” managed by National Research Foundation of Korea from Jul. 1 to Dec. 31, 2024.

### Description of the Related Art

Recently, interest in renewable energy as an alternative to existing fossil fuels due to regulations on carbon dioxide emissions and environmental issues such as global warming has been increasing. Among them, solar energy is attracting attention as an infinite and clean energy resource. A solar cell is a device that converts solar energy into electrical energy. However, in preparing a photo-active layer included in a solar cell, there is a problem in that upon coating using a solution containing organic materials, the shape of a thin film is significantly affected by humidity in the air. Further, in order to form a uniform thin film over a large area, a low-humidity environment such as a dry room or nitrogen environment is mandatory. Therefore, there is a need for developing a technique capable of forming a uniform photo-active layer over a large area under both low- and high-humidity conditions.

### SUMMARY OF THE INVENTION

An object according to one aspect of the present invention is to provide a composition for forming a photo-active layer, which is capable of improving the electrical characteristics of the photo-active layer while being capable of implementing a uniform thin film over a wide area, and a preparation method thereof.

In one aspect of the present invention, the present invention provides a composition for forming a photo-active layer, the composition including an electron donor material, an electron acceptor material, and an additive, wherein the additive is one or more selected from the group consisting of a carvone compound or derivatives thereof, a D-camphor compound or derivatives thereof, a phthalide compound or derivatives thereof, a benzonitrile compound or derivatives thereof, and a 2-methylcyclohexanone compound or derivatives thereof.

In another aspect, the present invention provides a photo-active layer including the composition for forming a photo-active layer.

In still another aspect, the present invention provides an organic solar cell including the photo-active layer.

In yet another aspect, the present invention provides a method for preparing the composition for forming the photo-active layer, the method including: preparing a solution including an electron donor material, an electron acceptor material, an additive, and a solvent; and evaporating the solvent, wherein the evaporating of the solvent can be performed under both a low-humidity condition of a relative humidity of 10% to 20% and a high-humidity condition of a relative humidity of 50% to 70%.

A composition for forming a photo-active layer and a preparation method thereof according to an embodiment of the present invention provide an effect in which it is possible to form a uniform thin film over a wide area regardless of the surface energy of a substrate through interaction with components, and to form a uniform thin film regardless of humidity by controlling the flow of a solution during the thin film formation process.

### BRIEF DESCRIPTION OF THE DRAWINGS

FIG. 1A is a schematic view illustrating a process of manufacturing a photo-active layer of an organic solar cell according to the related art.

FIG. 1B is a schematic view illustrating a process of manufacturing a photo-active layer of an organic solar cell according to an example of the present invention.

FIG. 2 is a graph illustrating the results of measuring a dielectric constant of a photo-active layer thin film according to an example of the present invention.

FIG. 3 is a graph illustrating a current density-voltage (J-V) curve of an organic solar cell according to an example of the present invention.

FIG. 4 is a graph illustrating the results of measuring the external quantum efficiency (EQE) of an organic solar cell according to an example of the present invention.

FIGS. 5A and 5B are graphs illustrating the crystallinity analysis results of an organic solar cell according to an example of the present invention.

FIG. 6 is an image illustrating the positions at which an average roughness is measured in an organic solar cell according to an example of the present invention.

FIG. 7 is a graph illustrating the results of analyzing the average roughness of an organic solar cell according to an example of the present invention.

FIG. 8 is an image illustrating the positions at which a power conversion efficiency is measured in an organic solar cell according to an example of the present invention.

FIG. 9 is a graph illustrating the results of analyzing the power conversion efficiency of an organic solar cell according to an example of the present invention.

FIG. 10 is a graph illustrating a current density-voltage (J-V) curve of an organic solar cell module according to an example of the present invention.

FIG. 11 is a graph illustrating the results of analyzing the power conversion efficiency of an organic solar cell module according to an example of the present invention.

### DETAILED DESCRIPTION OF THE INVENTION

Hereinafter, preferred examples of the present invention will be described in detail with reference to the accompanying drawings.

The examples of the present invention disclosed herein are exemplified for the purpose of describing the examples of the present invention only, and the examples of the present invention may be carried out in various forms and should not be construed to be limited to the examples described herein. Since the present invention may have various changes and different forms, it should be understood that the Examples are not intended to limit the present invention to specific disclosure forms and they include all the changes, equivalents and replacements included in the spirit and technical scope of the present invention.

In the present specification, when one part “includes” one constituent element, unless otherwise specifically described, this does not mean that another constituent element is excluded, but means that another constituent element may be further included.

The same reference numerals are attached to similar parts throughout the specification. Throughout the specification, when a part such as a layer, a film, a region, and a plate is present “on” or “over” another part, this includes not only a case where the part is present immediately on another part, but also a case where still another part is present therebetween. Throughout the specification, terms such as first and second may be used to describe various components, but the components should not be limited by the terms. The terms are used only to distinguish one component from another.

### Composition for Forming Photo-Active Layer

In one aspect of the present invention, the present invention provides a composition for forming a photo-active layer, the composition including an electron donor material, an electron acceptor material, and an additive, wherein the additive is one or more selected from the group consisting of a carvone compound or derivatives thereof, a D-camphor compound or derivatives thereof, a phthalide compound or derivatives thereof, a benzonitrile compound or derivatives thereof, and a 2-methylcyclohexanone compound or derivatives thereof.

In the present invention, the derivative means that a part of the oxygen or hydrogen contained in a compound is substituted with another element or substituent. In this case, the substituent is one or more functional groups selected from the group consisting of hydrogen; a substituted or unsubstituted alkyl group, alkenyl group, alkynyl group, alkoxy group, ester group, carbonyl group, amine group, or heteroalkyl group having 1 to 6 carbon atoms; a hydroxyl group; a thiol group; an amino group; a cyano group; a carboxyl group; an aldehyde group; a phosphate group; a diphosphate group; a sulfonic acid group, and a halogen.

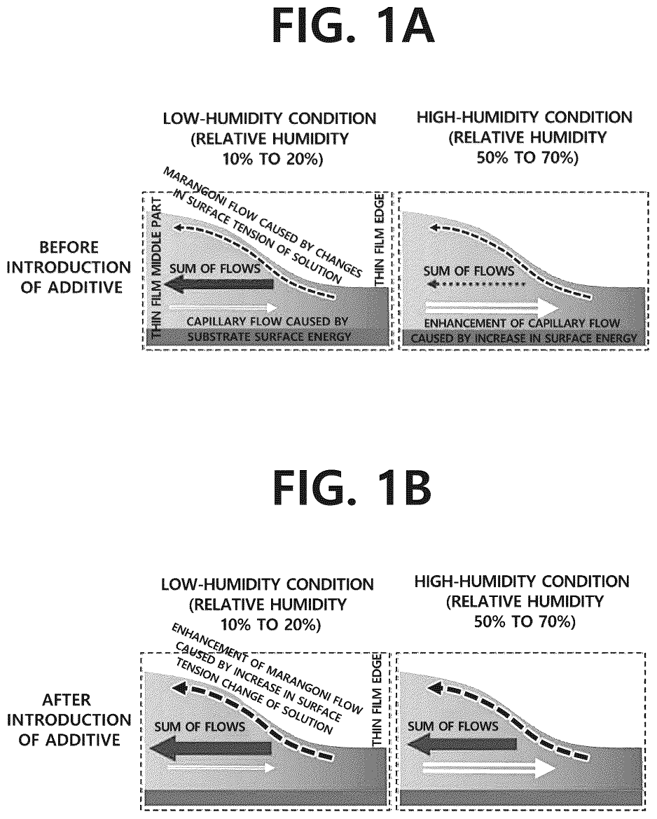

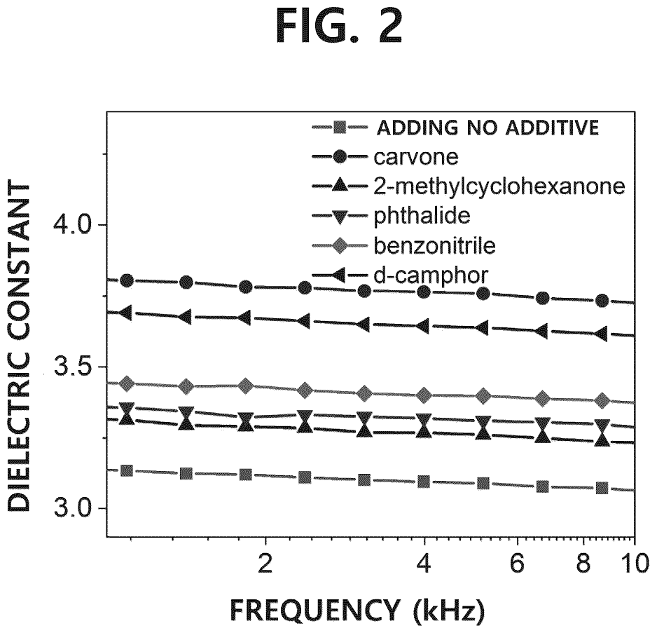

FIG. 1A is a schematic view illustrating a process of manufacturing a photo-active layer of an organic solar cell according to the related art. FIG. 1B is a schematic view illustrating a process of manufacturing a photo-active layer of an organic solar cell according to an example of the present invention.

As shown in FIG. 1A, when a substrate is exposed to a high-humidity environment, the capillary flow toward the edge of a thin film increases as the surface energy of the substrate increases, which is responsible for the formation of a non-uniform thin film. Thus, the present inventors have discovered that when an additive according to an example of the present invention is added to a solution for manufacturing a photo-active layer, a thin film with a uniform shape can be formed regardless of humidity, thereby completing the present invention. More specifically, as shown in FIG. 1B, when an additive according to an example of the present invention is introduced into a solution for manufacturing a photo-active layer, the change in surface tension of the solution caused by the evaporation of the solvent is increased, and accordingly, it is possible to increase the Marangoni flow, which is a flow toward the center of the thin film that is proportional to the change in surface tension. This effectively suppresses capillary flow, which is a flow toward the edges of a thin film, making it possible to form a thin film with a uniform shape regardless of humidity.

In an embodiment, the carvone compound is represented by the following Chemical Formula 1.

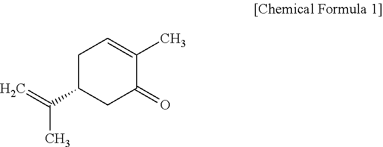

In an embodiment, the D-camphor compound is represented by the following Chemical Formula 2.

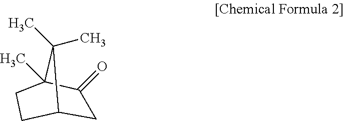

In an embodiment, the phthalide compound is represented by the following Chemical Formula 3.

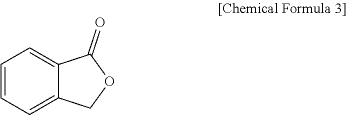

In an embodiment, the benzonitrile compound is represented by the following Chemical Formula 4.

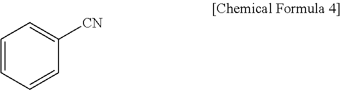

In an embodiment, the 2-methylcyclohexanone compound is represented by the following Chemical Formula 5.

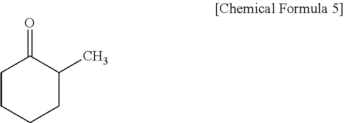

In an embodiment, the electron donor material is one or more selected from the group consisting of D18, PM6, and PTQ10.

In an embodiment, the D18 compound is represented by the following Chemical Formula 6.

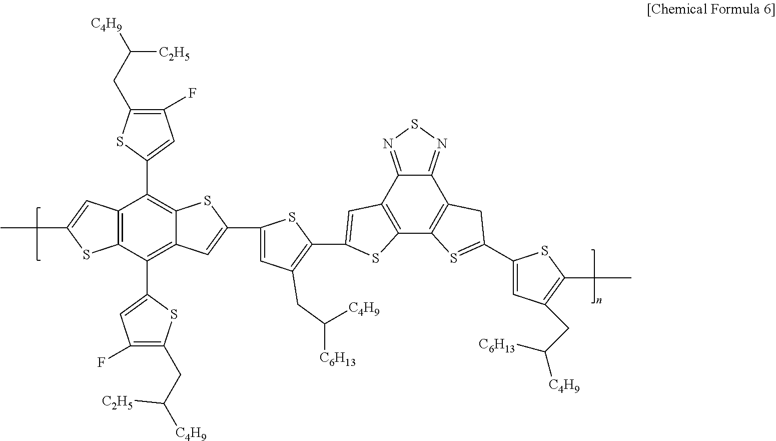

In an embodiment, the electron acceptor material is one or more selected from the group consisting of N3, Y6-BO, BTP-eC9, and L8-BO.

In an embodiment, the N3 compound is represented by the following Chemical Formula 7.

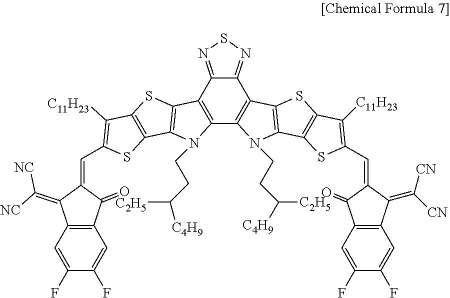

In an embodiment, the L8-BO compound is represented by the following Chemical Formula 8.

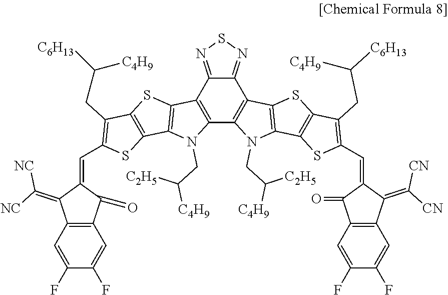

In an embodiment, the additive is a carvone compound or derivatives thereof.

In an embodiment, the additive is included at a content of 1 wt % to 10 wt % based on the total weight of the composition. More specifically, the content of the additive may be 1 wt % or more, 2 wt % or more, 3 wt % or more, 4 wt % or more, 5 wt % or more, 5.8 wt % or more; 10 wt % or less, 9 wt % or less, 8 wt % or less, 7 wt % or less, 6 wt % or less, 5.8 wt % or less, but is not limited thereto.

### Photo-Active Layer and Organic Solar Cell

In another aspect, the present invention provides a photo-active layer including the composition for forming a photo-active layer.

In an embodiment, the photo-active layer is a bulk-heterojunction (BHJ) type. According to the structure of the photo-active layer, organic solar cells are divided into a bi-layer p-n junction structure in which p-type and n-type semiconductors are composed of separate layers, and a bulk heterojunction (BHJ) type in which p-type and n-type semiconductors are mixed. The bulk heterojunction (BHJ) type solar cells is a solar cell in a form in which an active layer that generates electrons and holes is manufactured by mixing electron donor materials and electron acceptor materials in order to generate the maximum number of electron/hole pairs when irradiated with sunlight.

Since the present invention can be applied to the photo-active layer of a bulk heterojunction type organic solar cell, the present invention may be universally applied to the combination of various high-performance photo-active layers which have been recently reported.

In still another aspect, the present invention provides an organic solar cell including the photo-active layer. The organic solar cell is not particularly limited as long as it has a typical organic solar cell configuration, and basically includes a substrate, a first electrode (lower electrode), a hole transport layer, a photo-active layer, an electron transport layer, and a second electrode (upper electrode), but it is possible to add components such as a buffer layer according to the application or if necessary.

The organic solar cell according to the present invention may be used as a power source for wearable electronic devices and may be utilized as a sensor with a photodetector.

### Method for Preparing Composition for Forming Photo-Active Layer

In yet another aspect, the present invention provides a method for preparing the composition for forming a photo-active layer, the method including: preparing a solution including an electron donor material, an electron acceptor material, an additive, and a solvent; and evaporating the solvent, wherein the evaporating of the solvent can be performed under both a low-humidity condition of a relative humidity of 10% to 20% and a high-humidity condition of a relative humidity of 50% to 70%.

The preparation method according to the present invention provides an effect in which a composition for forming a photo-active layer can be easily prepared by a solution process without adding a separate process step. More specifically, when an additive according to an example of the present invention is introduced into a solution for manufacturing a photo-active layer, the change in surface tension of the solution caused by the evaporation of the solvent is increased, and accordingly, it is possible to increase the Marangoni flow, which is a flow toward the center of the thin film that is proportional to the change in surface tension. This effectively suppresses capillary flow, which is a flow toward the edges of a thin film, making it possible to form a thin film with a uniform shape regardless of humidity.

Hereinafter, the present invention will be described in detail with reference to preferred embodiments such that a person with ordinary skill in the art to which the present invention pertains can easily carry out the present invention. However, the present invention can be implemented in various different forms, and is not limited to the embodiments described herein.

### Examples

### <Preparation Example 1> Preparation of Composition for Forming Photo-Active Layer

A solution including D18 as an electron donor material, N3 and L8-BO as electron acceptor materials, and chloroform as a solvent was prepared. Subsequently, a carvone compound, a D-camphor compound, a phthalide compound, a benzonitrile compound, and a 2-methylcyclohexanone compound were added to the solution as additives. Subsequently, the solvent was evaporated from the mixture to prepare a composition for forming a photo-active layer. Subsequently, a photo-active layer thin film was manufactured from the composition for forming a photo-active layer.

### <Experimental Example 1> Measurement of Dielectric Constant of Photo-Active Layer Thin Film

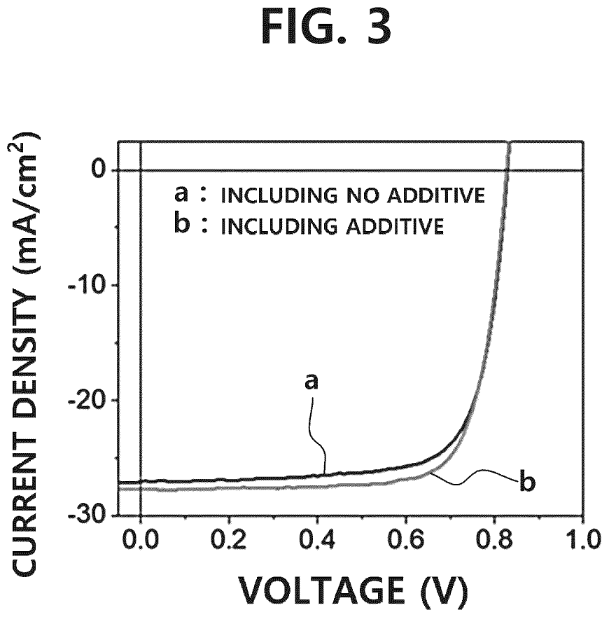

The dielectric constants of a total of five types of photo-active layer thin films prepared in Preparation Example 1 were measured. FIG. 2 is a graph illustrating the results of measuring a dielectric constant of a photo-active layer thin film according to an example of the present invention. From FIG. 2, it can be confirmed that the dielectric constant of the photo-active thin layer film increased after the addition of an additive, regardless of the type of additive. Since an increase in the dielectric constant facilitates separation of excitons generated from a photo-active layer into charge carriers, the electrical characteristics of the photo-active layer can be expected to be improved. In particular, it can be confirmed that among the five additive materials, the carvone compound increased the dielectric constant the most.

### <Preparation Example 2> Preparation of Organic Solar Cell

An organic solar cell was prepared using a photo-active layer thin film including a carvone compound as an additive.

### <Experimental Example 2> Evaluation of Cell Characteristics of Organic Solar Cell

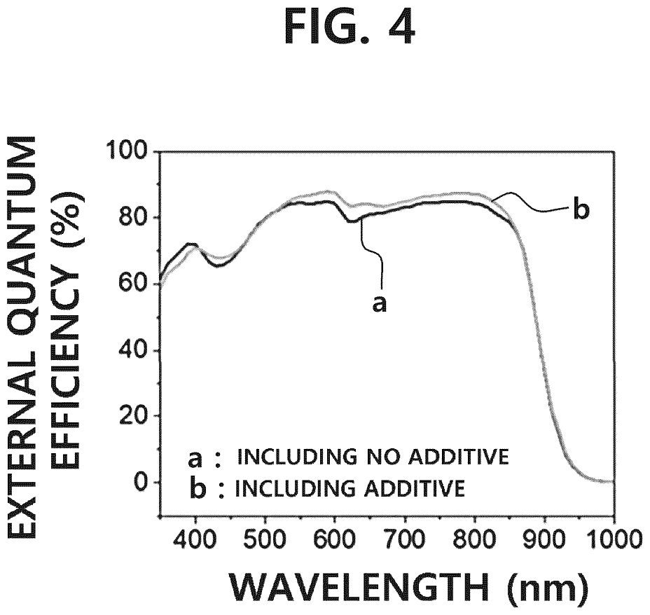

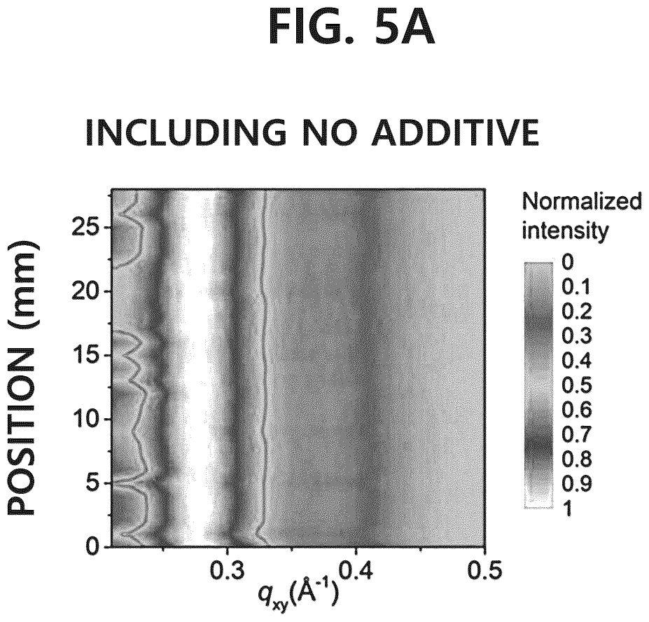

The cell characteristics of the organic solar cell manufactured in Preparation Example 2 was evaluated. FIG. 3 is a graph illustrating a current density-voltage (J-V) curve of an organic solar cell according to an example of the present invention. FIG. 4 is a graph illustrating the results of measuring the external quantum efficiency (EQE) of an organic solar cell according to an example of the present invention.

From FIG. 3, it can be confirmed that when an additive is added, the short-circuit current density is improved, thereby improving the solar cell characteristics. In addition, external quantum efficiency was measured to confirm the reason for the improvement in short-circuit current density, and from FIG. 4, it can be confirmed that the external quantum efficiency, which is a ratio of generated charges to incident photons, increases when an additive is added, so that the additive has a positive effect on the dissociation of excitons formed when irradiated with light.

### <Experimental Example 3> Evaluation of Thin Film Uniformity of Organic Solar Cell

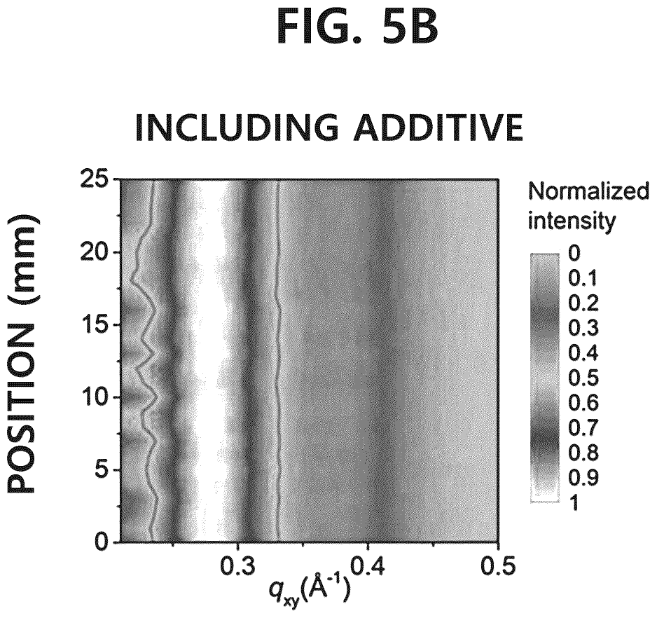

The thin film uniformity of the organic solar cell manufactured in Preparation Example 2 was evaluated. To confirm the uniformity of the large-area thin film, the crystallinity of the photo-active layer was analyzed in the longitudinal direction. FIGS. 5A and 5B are graphs illustrating the crystallinity analysis results of an organic solar cell according to an example of the present invention. From FIGS. 5A and 5B, it can be confirmed that the change in full width at half maximum according to position remains more constant when an additive is added compared to when no additive is added (gray solid line). Therefore, it can be seen that the crystallinity of the thin film becomes more constant over a wide area as the additive is added.

### <Experimental Example 4> Evaluation of Large-Area Uniformity of Organic Solar Cell

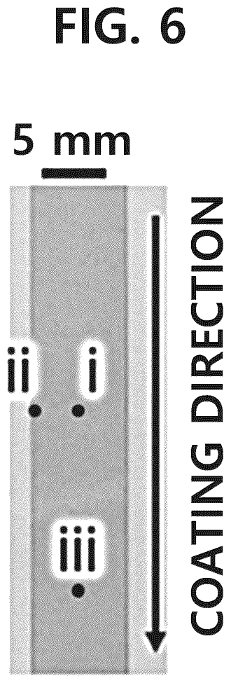

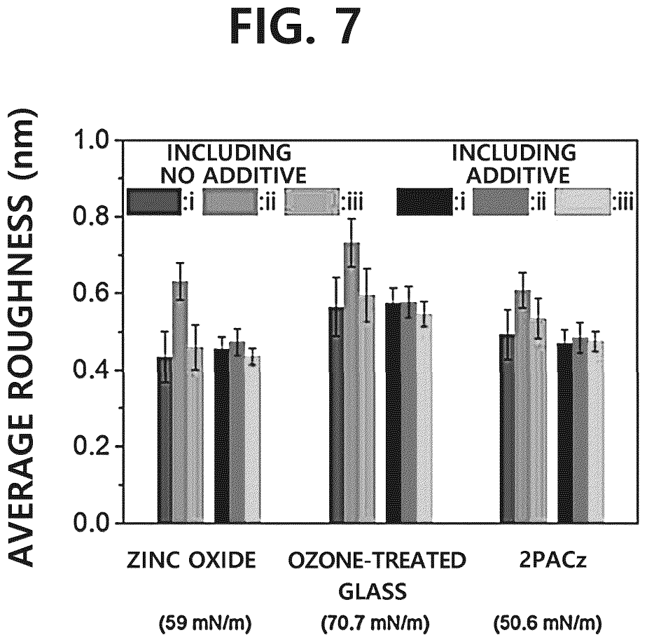

The large-area uniformity of the organic solar cell manufactured in Preparation Example 2 was evaluated. Photo-active layer thin films were manufactured on substrates with various surface energies (zinc oxide, ozone-treated glass, and 2PACz), and atomic force microscopy was performed at various positions to confirm an average roughness at each position. FIG. 6 is an image illustrating the positions at which an average roughness is measured in an organic solar cell according to an example of the present invention. FIG. 7 is a graph illustrating the results of analyzing the average roughness of an organic solar cell according to an example of the present invention.

From FIG. 7, it can be confirmed that the thin film including the additive has a smaller average roughness and a smaller distribution at each position than the thin film including no additive. From this, it can be seen that when an additive is added to the photo-active layer, a uniform and smoother thin film is formed over a large area.

### <Experimental Example 8> Evaluation of Power Conversion Efficiency of Organic Solar Cell

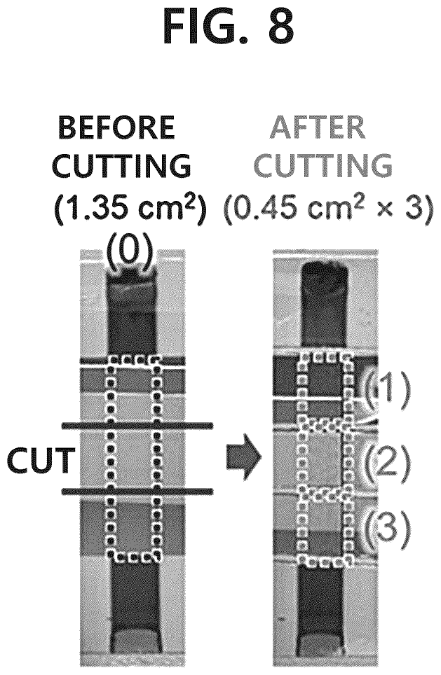

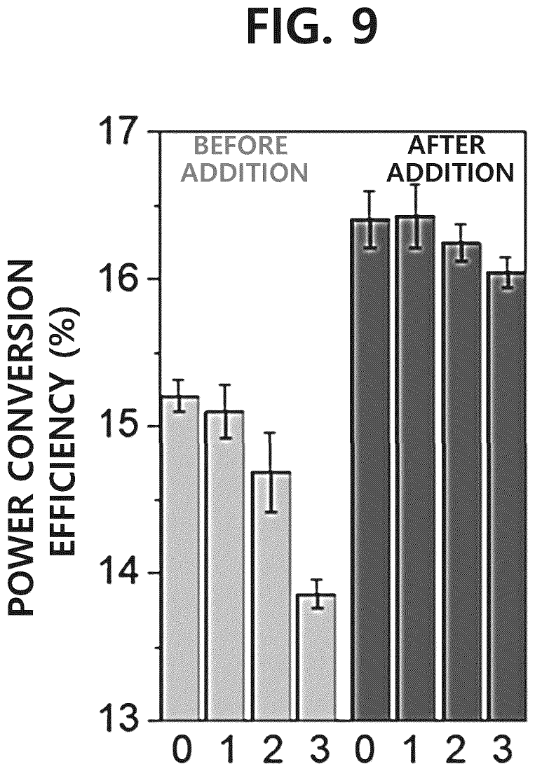

The power conversion efficiency (PCE) of the organic solar cell manufactured in Preparation Example 2 was evaluated. To confirm whether the organic solar cell forms a uniform thin film over a large area, a large-area organic solar cell element in the form of a bar was manufactured and cut into three equal parts to compare the solar cell characteristics at each position. FIG. 8 is an image illustrating the positions at which a power conversion efficiency is measured in an organic solar cell according to an example of the present invention. FIG. 9 is a graph illustrating the results of analyzing the power conversion efficiency of an organic solar cell according to an example of the present invention.

From FIG. 9, it can be confirmed that the element including the additive exhibits higher efficiency, and has a smaller performance deviation according to the position than the element including no additive. Therefore, it can be seen that the additive is effective in forming a more uniform photo-active layer over a large area.

### <Experimental Example 9> Evaluation of Electrical Characteristics of Organic Solar Cell Module

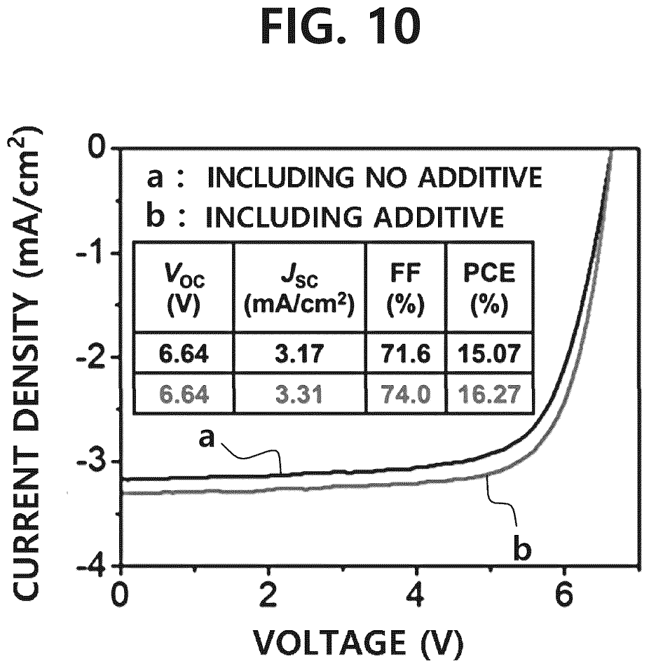

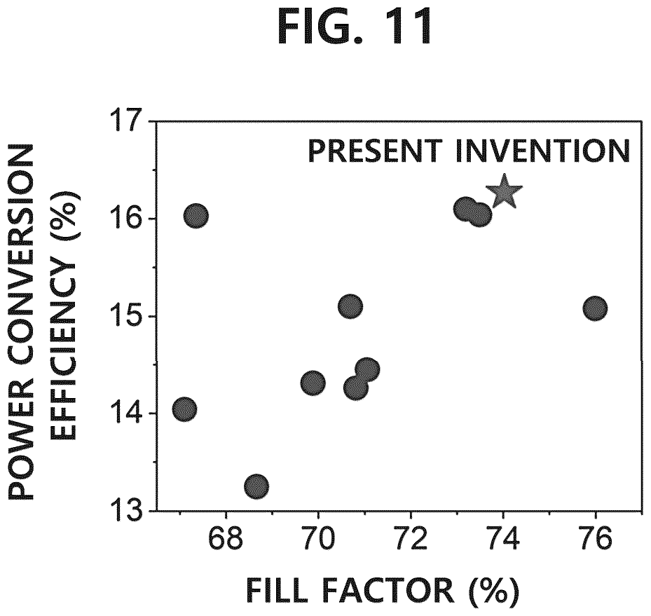

To evaluate the applicability of the organic solar cell manufactured in Preparation Example 2 to a large-area device, a large-area organic solar cell module having an area of 20 cm² was manufactured. FIG. 10 is a graph illustrating a current density-voltage (J-V) curve of an organic solar cell module according to an example of the present invention. FIG. 11 is a graph illustrating the results of analyzing the power conversion efficiency of an organic solar cell module according to an example of the present invention.

TABLE 1

| Additive | V_{OC} (V) | J_{SC} (mA cm⁻²) | FF (%) | PCE (%) |
|---|---|---|---|---|
| Not including | 6.64 | 3.17 | 71.6 | 15.07 |
| Including | 6.64 | 3.31 | 74.0 | 16.27 |

(V_{OC}: open circuit voltage, J_{SC}: short-circuit current density, FF: fill factor, PCE: power conversion efficiency).

From FIG. 10, it can be confirmed that as in the above-described unit element, after the additive is introduced, not only the short-circuit current density is improved, but also the filling rate of the element is enhanced as a uniform photo-active layer is formed over a large area, and the electrical characteristics of the photo-active layer are enhanced. From FIG. 11, it can be confirmed that the corresponding element exhibits the highest efficiency among the organic solar cell modules with an area of 20 cm² or more recently reported, so that the uniformity of the photo-active layer is secured over a large area.

### RECENTLY REPORTED LITERATURE

1) Joule 2024, 8, 970-978.
2) Adv. Mater. 2023, 35, 2301583.
3) Adv. Mater. 2024, 36, 2305424.
4) Joule 2022, 6, 2406-2422. (2 data)
5) Joule 2023, 7, 2386-2401.
6) Nat. Energy 2021, 6, 1045-1053.
7) Energy Environ. Sci. 2024, 17, 2935-2944.
8) Adv. Funct. Mater. 2024, doi: 10.1002/adfm.202401558
9) Adv. Sci. 2024, 11, 2404997

Although the exemplary embodiments of the present invention have been described above in conjunction with the preferred embodiments mentioned above, various modifications or variations can be made without departing from the spirit and scope of the invention. Therefore, it is intended that the appended claims cover all such modifications and variations as falling within the true spirit and scope of the present invention.

1. A photo-active layer thin film comprising an electron donor material, an electron acceptor material, and an additive,
wherein the additive is one or more selected from the group consisting of a carvone compound or derivatives thereof, a D-camphor compound or derivatives thereof, a phthalide compound or derivatives thereof, a benzonitrile compound or derivatives thereof, and a 2-methylcyclohexanone compound or derivatives thereof, and
wherein the photo-active layer thin film is prepared by a method comprising a step of evaporating a solvent from a solution comprising the electron donor material, the electron acceptor material, the additive, and the solvent.

2. The photo-active layer thin film of claim 1, wherein the additive is a carvone compound or derivatives thereof.

3. The photo-active layer thin film of claim 1, wherein the additive is comprised at a content of 1 wt % to 10 wt % based on a total weight of the composition.

4. A photo-active layer comprising the photo-active layer thin film of claim 1.

5. The photo-active layer of claim 4, wherein the photo-active layer is a bulk heterojunction (BHJ) type.

6. An organic solar cell comprising the photo-active layer of claim 4.
